(19) United States
(12) Patent Application Publication
(10) Pub. No.: US 2007/0267629 A1
(43) Pub. Date: Nov. 22, 2007

(54) LASER IRRADIATION DEVICE AND METHOD OF FABRICATING OLED USING THE SAME

(75) Inventors: Noh-Min KWAK, Suwon-si (KR); Tae-Min Kang, Suwon-si (KR); Jae-Ho Lee, Suwon-si (KR); Jin-Soo Kim, Suwon-si (KR); Dae-Woo Lee, Suwon-si (KR); Seong-Taek Lee, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/751,294

(22) Filed: May 21, 2007

(30) Foreign Application Priority Data
May 22, 2006 (KR) 10-2006-0045887

(51) Int. Cl. H01L 29/08; H01L 35/24; H01L 51/40; H01L 51/00

(52) U.S. Cl. 257/40; 438/99

(57) ABSTRACT

A laser irradiation device and a method of fabricating an OLED having an increased laser efficiency. The laser irradiation device includes: a light source to produce a laser beam; a collimation lens disposed adjacent to the light source; and an asymmetrical micro lens array disposed adjacent to the collimation lens. The method includes: providing a substrate having a first electrode; providing a donor substrate for laser transfer, including a sequentially stacked a base layer, a light-to-heat conversion layer, and a transfer layer; disposing the donor substrate on the substrate so that the transfer layer faces the substrate; and irradiating a predetermined region of the base layer using a laser irradiation device having a light source, a collimation lens, and an asymmetrical micro lens array, to transfer the transfer layer onto the substrate, and forming an organic layer pattern on the substrate.

### CROSS-REFERENCE TO RELATED APPLICATIONS

This application claims the benefit of Korean Application No. 2006-45887, filed May 22, 2006, in the Korean Intellectual Property Office, the disclosure of which is incorporated herein by reference.

### BACKGROUND OF THE INVENTION

1. Field of the Invention

Aspects of the present invention relate to a laser irradiation device and a method of fabriciating an organic light emitting display (OLED) using the same.

2. Description of the Related Art

Generally, an OLED used in a flat panel display, includes an anode electrode, a cathode electrode, and an organic layer interposed between the anode electrode and the cathode electrode. The organic layer may include at least an organic emissive layer. OLEDs can be classified as polymer OLEDs or low molecular weight OLEDs, depending on the material forming the organic emissive layer.

In order to realize a full-color OLED, emissive layers representing the three primary colors of red, green and blue have to be patterned therein. A method of patterning the emissive layer may include, for a low molecular OLED, using a shadow mask, or for a polymer OLED, using an ink-jet printing or laser induced thermal imaging (hereinafter referred to as LITI). Among these methods, the LITI method is advantageous in that the organic layer can be finely patterned and adapted to a large-sized screen. In addition, the LITI method is well suited for obtaining a high resolution display. Further, the LITI method is a dry process, rather than a wet process, like ink-jet printing.

FIG. 1 is a schematic cross-sectional view illustrating a method of fabricating an OLED using a conventional laser irradiation device.

Referring to FIG. 1, a substrate 161, having a first electrode 162, is provided. A thin film transistor and a capacitor may be disposed between the first electrode 162 and the substrate 161. A donor substrate 150 is laminated onto the substrate 161. The donor substrate 150 includes a base layer 151, a light-to-heat conversion layer 152, and a transfer layer 153.

A gas generation layer (not shown) may be further disposed between the light-to-heat conversion layer 152 and the transfer layer 153. A laser irradiation device 100 is provided separately from the substrate 161 and the donor substrate 150. The laser irradiation device 100 includes a light source 110, a patterned mask 120, and a projection lens 130.

A laser beam 140, emitted from the light source 110, passes through the patterned mask 120, is refracted by the projection lens 130, and is then focused onto a predetermined region of the base layer 151.

The laser beam 140 is absorbed by the light-to-heat conversion layer 152 and is converted into heat energy. The heat energy causes the transfer layer 153 to adhere to the substrate 161. The heat energy can weaken the adhesion between the transfer layer 153 and the light-to-heat conversion layer 152. The weakened adhesion allows the transfer layer 153, or an irradiated portion thereof, to remain attached to the substrate 161 when the heat-to-light conversion layer 152 is separated from the substrate 161. In this way the transfer layer 153, or a portion thereof, is transferred from the heat-to-light conversion layer 152 to the substrate 161.

However, in the conventional laser irradiation device, there are problems in that a mask should be exchanged depending on the model and the pattern size of a unit pixel, and thus, the processing time and manufacturing cost increase. In addition, the mask of the conventional laser irradiation decreases the efficiency of the laser beam. Further, when the laser power is increased, the mask may be bent.

### SUMMARY OF THE INVENTION

Aspects of the present invention provide a laser irradiation device and a method of fabricating an OLED using the same, capable of effectively utilizing a laser beam, and reducing processing time and manufacturing cost.

In an exemplary embodiment of the present invention, a laser irradiation device for increasing use efficiency of a laser beam includes: a light source; a collimation lens disposed under the light source; and an asymmetrical micro lens array disposed under the collimation lens.

In another exemplary embodiment, according to aspects of the present invention, a method of fabricating an OLED includes: providing a substrate including a first electrode; providing a donor substrate for laser transfer, fabricated by sequentially stacking a base layer, a light-to-heat conversion layer, and a transfer layer; disposing the donor substrate on the substrate so that the transfer layer faces the substrate; and directing a laser beam onto a predetermined region of the base layer. The laser beam can be generated using a laser irradiation device having a light source, a collimation lens, and an asymmetrical micro lens array. The laser beam can be used to transfer the transfer layer onto the substrate, and form an organic layer pattern on the substrate.

Additional aspects and/or advantages of the invention will be set forth in part in the description which follows, and in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic cross-sectional view illustrating a method of fabricating an OLED, using a conventional laser irradiation device;

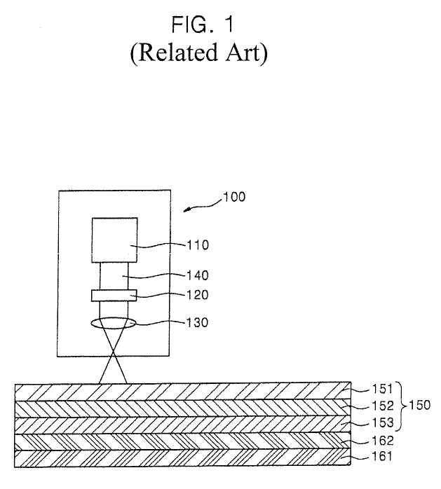

FIG. 2A is a schematic cross-sectional view illustrating a method of fabricating an OLED, using a laser irradiation device, in accordance with an exemplary embodiment of the present invention; and

FIG. 2B is a schematic perspective view showing a relationship between an asymmetrical micro lens and a pixel to be irradiated by a laser irradiation device, in accordance with an exemplary embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Herein, when a layer is said to be “disposed on” another layer or a substrate, the phrase refers to a layer that may be directly formed on the other layer, or that a third layer may be interposed therebetween. In addition, the thickness of layers and regions may be exaggerated for clarity.

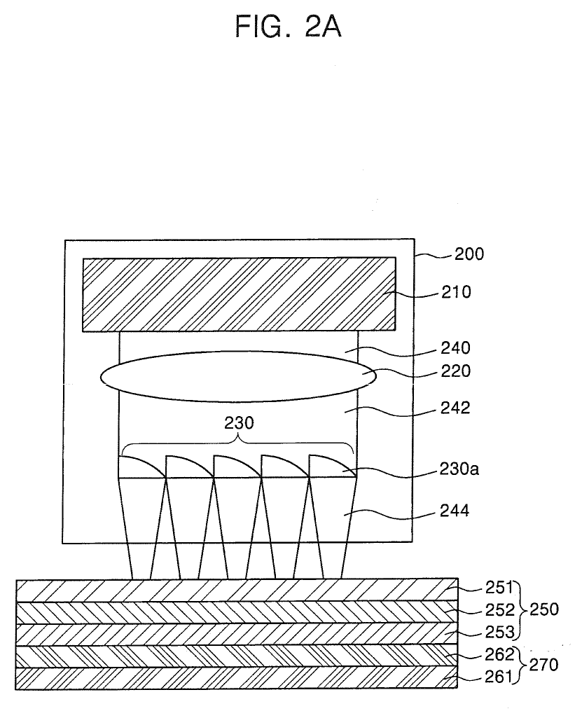

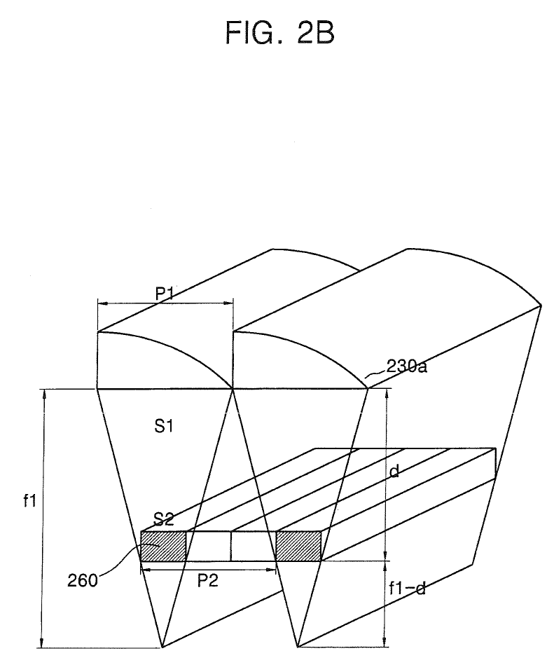

FIG. 2A is a schematic cross-sectional view illustrating a method of fabricating an OLED using a laser irradiation device, in accordance with an exemplary embodiment of the present invention.

Referring to FIG. 2A, a base substrate 270, including a substrate 261, and a first electrode 262 are provided. A thin film transistor (not shown), an insulating layer (not shown), a capacitor (not shown), and so on, may be further disposed between the substrate 261 and the first electrode 262.

A donor substrate 250 is initially provided as a separate component with respect to the base substrate 270. The donor substrate 250 includes a base layer 251, a light-to-heat conversion layer 252 deposited on the base layer 251, and a transfer layer 253 deposited on the light-to-heat conversion layer 252. A gas generation layer (not shown) may be further disposed between the light-to-heat conversion layer 252 and the transfer layer 253.

The base layer 251 can be a transparent material to transmit light to the light-to-heat conversion layer 252. The base layer 251 can be a material having appropriate optical properties and sufficient mechanical stability. For example, the material may include glass or at least one polymer material selected from the group consisting of a polyester, a polyacryl, a polyepoxy, a polyethylene, and a polystylene. The base layer 251 may be formed of polyethylene terephthalate. The base layer 251 may function as a support substrate.

The light-to-heat conversion layer 252 absorbs infrared and/or ultraviolet wavelengths. The light-to-heat conversion layer 252 may include an optical absorption material to absorb light and to convert a portion of the light into heat. The light-to-heat conversion layer 252 may be formed as a metal layer comprising Al, Ag, an oxide thereof and/or a sulfide thereof. The light-to-heat conversion layer 252 may be formed as an organic layer formed of a polymer including carbon black, graphite, or an infrared dye. The metal layer may be formed by a vacuum deposition method, an electron beam deposition method, or a sputtering method. The organic layer may be formed by a general film coating method such as gravure, extrusion, spin coating, and knife coating.

The gas generation layer (not shown) may comprise pentaerythritol tetranitrate (PETN), trinitrotoluene (TNT), or the like. When the gas generation layer absorbs light or heat, a decomposition reaction is conducted to discharge nitrogen gas, hydrogen gas, or the like to provide transfer energy.

The transfer layer 253 may comprise a single layer or may comprise a multiple layers (not shown) selected from the group consisting of a hole injection layer, a hole transport layer, an organic emissive layer, a hole blocking layer, an electron transport layer, an electron injection layer, and a combination thereof.

The hole injection layer can be used to perform hole injection into an organic emissive layer of an OLED. The hole injection layer can increase the lifespan of the OLED. The hole injection layer may comprise an arylamine-based compound, a starburst amine-based material, and the like. More specifically, the hole injection layer may be formed of 4,4′,4″-tris(3-methylphenylamino)triphenylamie (m-MTDATA), 1,3,5-tris[4-(3-methylphenylamino)phenyl]benzene (m-MTDATB), and/or copper phthalocyanine (CuPc).

The hole transport layer may be formed of arylene diamine derivatives, a starburst compound, biphenyldiamine derivatives having spiro-base, and/or a ladder compound. More specifically, the hole transport layer may be formed of N,N-diphenyl-N,N′-bis(4-methylphenyl)-1,1′-biphenyl-4,4′-diamine (TPD), or 4,4-bis[N-(1-napril)-N-phenylamino]biphenyl (NPB).

The organic emissive layer may be formed of a red luminescent material such as a low molecular material e.g., Alq3(host)/DCJTB(fluorescent dopant), Alq3(host)/DCM(fluorescent dopant), CBP(host)/PtOEP(phosphorescent organic metal complex), or the like, and a polymer material, e.g., a PFO-based polymer, a PPV-based polymer, or the like; a green luminescent material such as a low molecular material e.g., Alq3, Alq3(host)/C545t(dopant), CBP(host)/IrPPy(phosphorescent organic metal complex), or the like, and a polymer material, e.g., a PFO-based polymer, a PPV-based polymer, or the like; and a blue luminescent material such as a low molecular material e.g., DPVBi, spiro-DPVBi, spiro-6P, distyryl benzene (DSB), distyryl arylene (DSA), or the like, and a polymer material, e.g., a PFO-based polymer, a PPV-based polymer, or the like.

The hole blocking layer is to prevent the movement of a hole into an electron injection layer, when the electron mobility is greater than the hole mobility in an organic emissive layer. The hole blocking layer may comprise a material selected from the group consisting of 2-biphenyl-4-il-5-(4-t-butylphenyl)-1,3,4-oxidiazole (PBD), spiro-PBD, and 3-(4′-t-butylphenyl)-4-phenyl-5-4(4′-biphenyl)-1,2,4-triazole (TAZ).

The electron transport layer may comprise a metal compound capable of readily accommodating an electron, for example, a 8-hydroquinoline aluminum salt capable of stably transporting an electron supplied from a cathode electrode.

The electron injection layer may comprise at least one material selected from the group consisting of 1,3,4-oxidiazole derivatives, 1,2,4-triazole derivatives, and LiF.

In addition, the organic layer may be formed by extrusion, spin coating, knife coating, vaccum deposition, CVD, or the like.

The donor substrate 250 may further include various layers having different purposes, in addition to the above layers. The structure of the various layers can be a deposition structure that can be modified depending on its intended use.

Then, a pixel region of the substrate 261 and a transfer layer 253 of the donor substrate 250 are disposed in opposition to each other, and then can be evenly laminated together.

The lamination can be performed by pressing the donor substrate 250 to the base substrate 270, using a roller, a gas press, or a crown press. The lamination may be performed from the center to the periphery, or in a single linear direction, for example, from one edge to an opposing edge. When the lamination is performed by pressing from the center to the periphery, it is possible to effectively prevent the formation of bubbles between the donor substrate 250 and the base substrate 270.

A laser irradiation device 200 is provided separately from the base substrate 270 and the donor substrate 250. The laser irradiation device 200 includes a light source 210, a collimation lens 220, and an asymmetrical micro lens array 230. The light source 210 generates a laser beam 240. The laser beam 240 can be used to separate the transfer layer 253 from the donor substrate 250 and to transfer the transfer layer 253 onto the substrate 261. The laser beam 240 can be used to selectively irradiate a portion of the transfer layer that corresponds to a desired deposition pattern. The portion of the transfer layer 253 can be transferred to the base substrate 270, while the remaining portion of the transfer layer 253 can remain attached to the light-to-heat conversion layer 252.

The collimation lens 220 is to convert the laser beam 240, emitted from the light source 210, into a collimated beam 242, i.e. a laser beam having parallel rays and/or a planar wave front. The collimation lens 220 can reciprocate to positions between the light source 210 and the asymmetrical micro lens array 230. The collimation lens 220 can be incorporated into the light source 210.

The asymmetrical micro lens array 230 is to form a plurality of sub-beams 244 from the collimated beam 242. The lens array 230 can focus each sub-beam 244, to allow the efficient use of the light energy from the light source 210. For example, the asymmetrical micro lens array 230 can redirect portions of a laser beam that would have been blocked by a conventional mask patterning system, thereby increasing the use efficiency of the laser beam. In addition, the asymmetrical micro lens array 230 is to define one or more pixels to be patterned. For example, the asymmetrical micro lens array 230 can focus the sub-beams 244 into a pattern, such as a deposition pattern corresponding to a pattern of deposited pixels.

The asymmetrical micro lens array 230 may comprise a plurality of asymmetrical micro lenses 230a. The micro lenses 230a can be asymmetrically shaped to focus one of the sub-beams 244. For example, the micro lenses 230a can have an asymmetric top surface and a flat bottom surface. As a result, the laser irradiation device 200 can perform a multi-scan method that can simultaneously pattern a plurality of the same colored pixels, when fabricating the OLED. The multi-scan method can comprise forming a deposition pattern for a first set of pixels, forming a deposition pattern for a second set of pixels, and then forming a deposition pattern for a third set of pixels. For example the first, second, and third sets of pixels can be R, G, and B pixels, respectively.

The asymmetrical micro lens array 230 may reciprocate to positions between the collimation lens 220 and the donor substrate 250, to adjust the focal distance of the asymmetrical micro lenses 230a, and/or to adjust the deposition pattern size, thereby adjusting the corresponding pattern of deposited pixels. The asymmetrical micro lens array 230 may be formed of a transparent material such as glass or plastic. The asymmetrical micro lens array 230 can produce a deposition pattern having a widened gap between pixels, in comparison with a symmetrical micro lens array. As a result, the R, G and B pixels can be disposed with a uniform interval therebetween, and it is possible to prevent the misalignment of deposition patterns, which results in R, G and B pixels that are not separated. Therefore, it is possible to precisely adjust the interval between the pixels, thereby fabricating a compact OLED.

FIG. 2B is a schematic perspective view showing a relationship between an asymmetrical micro lenses 230a and unit pixels 260, to be irradiated by a laser irradiation device, in accordance with an exemplary embodiment of the present invention. The pitch of the asymmetrical micro lenses 230a is represented by P1. The width of the asymmetrical micro lenses 230a is represented by S1. The focal distance of the asymmetrical micro lenses 230a is represented by f1. The distance from the asymmetrical micro lenses 230a to the bottom of unit pixels 260 is represented by d. The width of the unit pixels 260 is represented by S2. The width of 3 unit pixels 260, i.e. R, G, and B unit pixels, is represented by P2.

The focal distance f1, of the asymmetrical micro lenses 230a, can have a range of about 10-300 mm. When the focal distance f1 is less than 10 mm, it can be difficult to dispose subsidiary components between the substrate and the lenses 230a, during patterning, in addition to the donor substrate. As a result, it can be difficult for the apparatus to be smoothly operated, due to a lack of space during scanning and/or patterning. In addition, when the focal distance f1 is more than 300 mm, the apparatus may be unnecessarily large.

The distance d can be in a range of about ⅔ the range of distance f1, for example a range of about 20/3-200 mm (6⅔-200). The reasons for defining the distance d in this way are similar to the reasons stated above, for the range of the focal distance f1.

When an array of pixels is fabricated with approximately 50-300 ppi (pixels per inch), the width P2 can be in the range of about 60-500 μm. In addition, the width P1, of the asymmetrical micro lenses 230a, is equal to the width P2. The range of the width S2 is about ⅓ the range of width P2, for example a range of about 20-500/3 μm.

The above description is represented as the following formulae:

P2:S2=3:1 Formula (1)

### Using triangular theory

f1:f1−d=3:1 Formula (2)

f1:f1−d=S1:S2 Formula (3)

From Formula (2), d=2×f1/3 Formula (4)

### In Formula (3), since P1 is equal to S1,

(f1−d)×P1=f1×S2 Formula (5)

### Substituting Formula (4) into Formula (5)

S2=P1/3 Formula (6)

For example, when a 17-inch UXGA is fabricated, the number of pixels is 1600×1200. The pitch of the pixeles is 72×216 μm. For this application, the laser irradiation device may be designed as follows:

when f1 is 20 cm, S2 is 72 μm; and

using Formula (6), P1 is 216 μm, and d is 13.34 cm.

Referring again to FIG. 2A, the laser beam 240, emitted from the light source 210 of the laser irradiation device 200, passes through the collimation lens 220 to form the collimated beam 242. The collimated beam 242 passes through the asymmetrical micro lenses 230a and is split into the sub-beams 244. The sub-beams 244 form a pixel pattern, in the transfer layer 253, corresponding to a pattern of the pixel regions to be deposited on the base substrate 270. The pattern of the pixel regions is automatically adjusted by the asymmetrical micro lenses 230a. The sub-beams 244 irradiate a predetermined region of the donor substrate 250, to transfer the transfer layer 253 onto the substrate 261, thereby forming an organic layer pattern (not shown).

The organic layer pattern may be transferred in a transfer process using an N₂ atmosphere, to prevent the oxidation of the organic layer pattern, due to the presence of oxygen. However, the formation of a complete N₂ atmosphere is a costly and time consuming operation. Therefore, an enriched N₂ atmosphere may be used, having conditions such that that the organic layer is not affected by oxygen or moisture. For example, an enriched N₂ atmosphere may be created for the transfer process, by charging an atmosphere with N₂ until O₂ and H₂O are each present in a concentration of less than 100 ppm.

In addition, the transfer process may be performed under a vacuum, to suppress the generation of bubbles between the donor substrate 250 and the base substrate 270, during lamination of the donor substrate 250 onto the surface of the base substrate 270.

As can be seen from the foregoing, it is possible to reduce the processing time and the manufacturing costs, by fabricating an OLED using a laser irradiation device including an asymmetrical micro lens array. Therefore, it is possible to increase the reliability and the yield of OLED's produced by the process and/or by using such a device.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A laser irradiation device to form deposition patterns in a transfer layer, the laser irradiation device comprising:
a light source to produce a laser beam;
a collimation lens to form a collimated beam from the laser beam, disposed under the light source; and
an asymmetrical micro lens array disposed under the collimation lens.

2. The laser irradiation device according to claim 1, wherein the asymmetrical micro lens array is made of a set of asymmetrical micro lenses consisting of a transparent material.

3. The laser irradiation device according to claim 1, wherein the asymmetrical micro lens array is movable relative to the transfer layer.

4. The laser irradiation device according to claim 1, wherein the asymmetrical micro lens array has a focal distance of 10-300 mm.

5. The laser irradiation device according to claim 1, wherein the asymmetrical micro lens array comprises a plurality of lenses having widths of about 60-500 μm.

6. The laser irradiation device according to claim 2, wherein the transparent material comprises one of a glass and a transparent plastic.

7. A method of fabricating an OLED, from a base substrate comprising an electrode and a donor substrate comprising a transfer layer and a light-to-heat conversion layer, the method comprising:
disposing the donor substrate on the base substrate so that the transfer layer contacts the base substrate;
using a laser irradiation device comprising an asymmetrical micro lens array, a light source and a collimation lens, to form a deposition pattern in the transfer layer, to transfer a portion of the transfer layer onto the substrate; and
separating the base substrate from the donor substrate to forming a pixel pattern on the base substrate.

8. The method according to claim 7, wherein the donor substrate further comprises a gas generation layer disposed between the light-to-heat conversion layer and the transfer layer.

9. The method according to claim 7, wherein the asymmetrical micro lens array is made of a plurality of asymmetrical micro lenses formed of a transparent material.

10. The method according to claim 7, wherein the asymmetrical micro lens array is movable in relation to the collimation lens and the donor substrate.

11. The method according to claim 7, wherein the asymmetrical micro lens array has a focal distance of about 10-300 mm.

12. The method according to claim 9, wherein the plurality of asymmetrical micro lenses have widths of about 60-500 μm.

13. The method according to claim 7, wherein the asymmetrical micro lens array is spaced apart from the donor substrate by a distance of about 20/3-200 mm.

14. The method according to claim 7, wherein the pixel pattern comprises pixels having widths of about 20-500/3 μm.

15. The method according to claim 7, wherein the laser irradiation device performs a multi-scan method.

16. The method of claim 7, wherein the pixel pattern comprises an organic layer.

17. The laser irradiation device according to claim 1, wherein the asymmetrical micro lens array divides the collimated beam into a plurality of sub-beams.

18. The laser irradiation device according to claim 17, wherein the sub-beams form deposition patterns in the transfer layer.
